(19) United States
(12) Patent Application Publication
(10) Pub. No.: US 2015/0228531 A1
(43) Pub. Date: Aug. 13, 2015

(54) INTEGRATED CIRCUIT DEVICE AND METHOD FOR MANUFACTURING SAME

(71) Applicant: Kabushiki Kaisha Toshiba, Minato-ku (JP)

(72) Inventor: Masayoshi TAGAMI, Kuwana-shi (JP)

(73) Assignee: Kabushiki Kaisha Toshiba, Minato-ku (JP)

(21) Appl. No.: 14/320,959

(22) Filed: Jul. 1, 2014

(30) Foreign Application Priority Data
Feb. 12, 2014 (JP) 2014- 024698
Feb. 20, 2014 (JP) 2014-031034

(51) Int. Cl. H01L 21/768; H01L 23/532; H01L 23/522

(52) U.S. Cl. CPC H01L 21/7682; H01L 21/76843; H01L 21/76877; H01L 23/5226; H01L 23/5329

(57) ABSTRACT

A method for manufacturing an integrated circuit device according to the embodiment includes forming a silicon film on a first insulating film, making a plurality of trenches to pierce the silicon film by etching the silicon film, forming a plurality of interconnects by filling a metal material into the trenches, removing the silicon film, and forming a second insulating film on the plurality of interconnects without filling a gap between the interconnects.

### CROSS-REFERENCE TO RELATED APPLICATIONS

This application is based upon and claims the benefit of priority from Japanese Patent Application No. 2014-024698, filed on Feb. 12, 2014, and Japanese Patent Application No. 2014-031034, filed on Feb. 20, 2014; the entire contents of which are incorporated herein by reference.

### FIELD

Embodiments described herein relate generally to an integrated circuit device and a method for manufacturing the same.

### BACKGROUND

In recent years, technology is being proposed for an integrated circuit device in which multiple trenches are made in an inter-layer insulating film; interconnects are formed by filling a metal material into the trenches; and air gaps are made between the interconnects by removing portions of the inter-layer insulating film disposed between the interconnects. However, by such technology, it is difficult to make the trenches to have uniform depths; and it is difficult to remove the inter-layer insulating film uniformly.

### BRIEF DESCRIPTION OF THE DRAWINGS

FIGS. 1A to 3B are cross-sectional views showing a method for manufacturing an integrated circuit device according to a first embodiment;

FIGS. 4A to 5C are partially-enlarged cross-sectional views showing the method for manufacturing the integrated circuit device according to the first embodiment;

FIGS. 6A to 13E are views showing a method for manufacturing an integrated circuit device according to a second embodiment;

FIGS. 14A to 17B are cross-sectional views showing a method for manufacturing an integrated circuit device according to a third embodiment; and

FIG. 18 is a partially-enlarged cross-sectional view showing region R6 of FIG. 17B.

### DETAILED DESCRIPTION

An integrated circuit according to the embodiment includes a first insulating film, a plurality of interconnects provided on the first insulating film to extend in a first direction, a barrier metal layer provided on a side surface of the interconnects, a silicon oxide layer provided on a side surface of the barrier metal layer, and a second insulating film provided on the plurality of interconnects. An air gap is made between the interconnects, and the silicon oxide layer is disposed between the air gap and the barrier metal layer.

A method for manufacturing an integrated circuit device according to the embodiment includes forming a silicon film on a first insulating film, making a plurality of trenches to pierce the silicon film by etching the silicon film, forming a plurality of interconnects by filling a metal material into the trenches, removing the silicon film, and forming a second insulating film on the plurality of interconnects without filling a gap between the interconnects.

### First Embodiment

Embodiments of the invention will now be described with reference to the drawings.

First, a first embodiment will now be described.

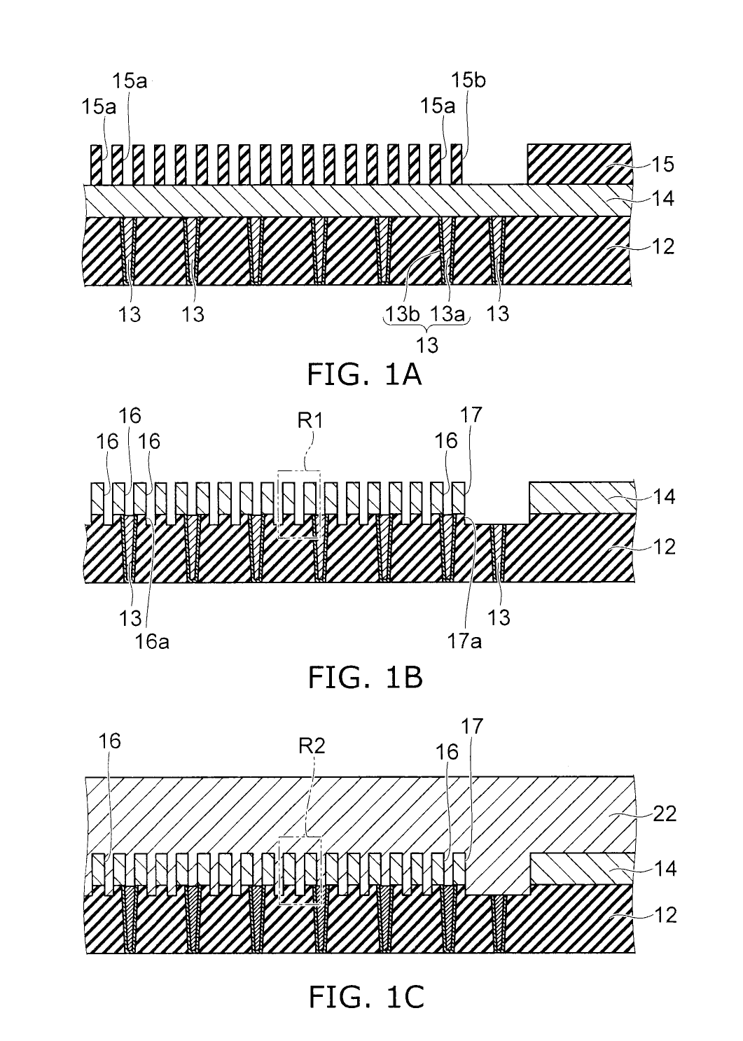

FIGS. 1A to 1C, FIGS. 2A to 2C, and FIGS. 3A and 3B are cross-sectional views showing a method for manufacturing an integrated circuit device according to the embodiment.

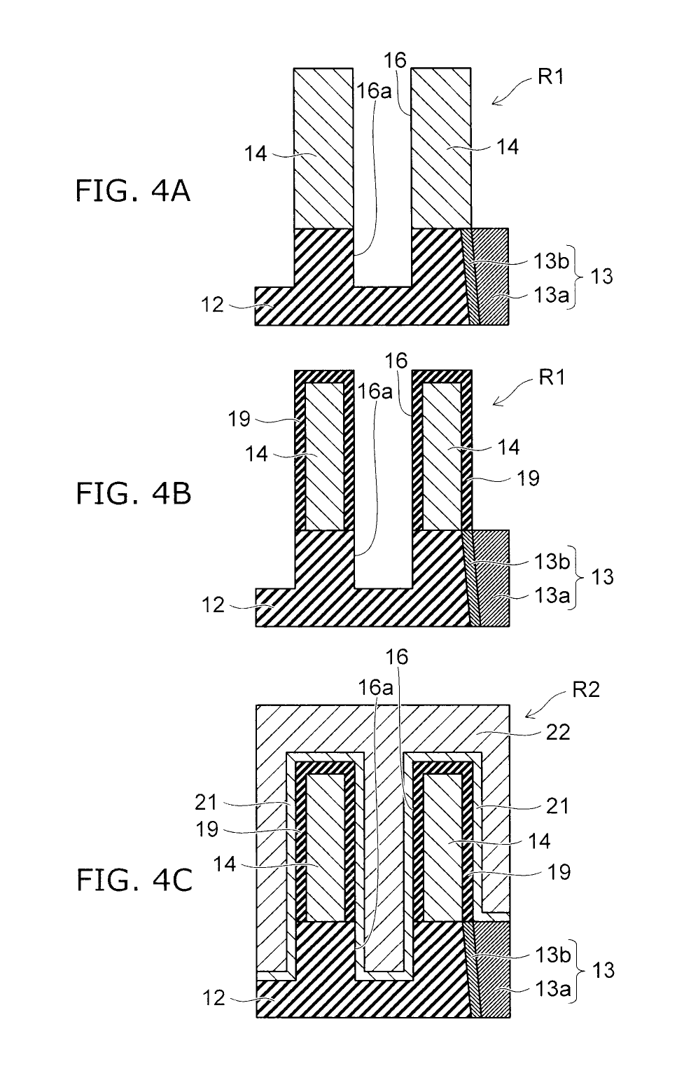

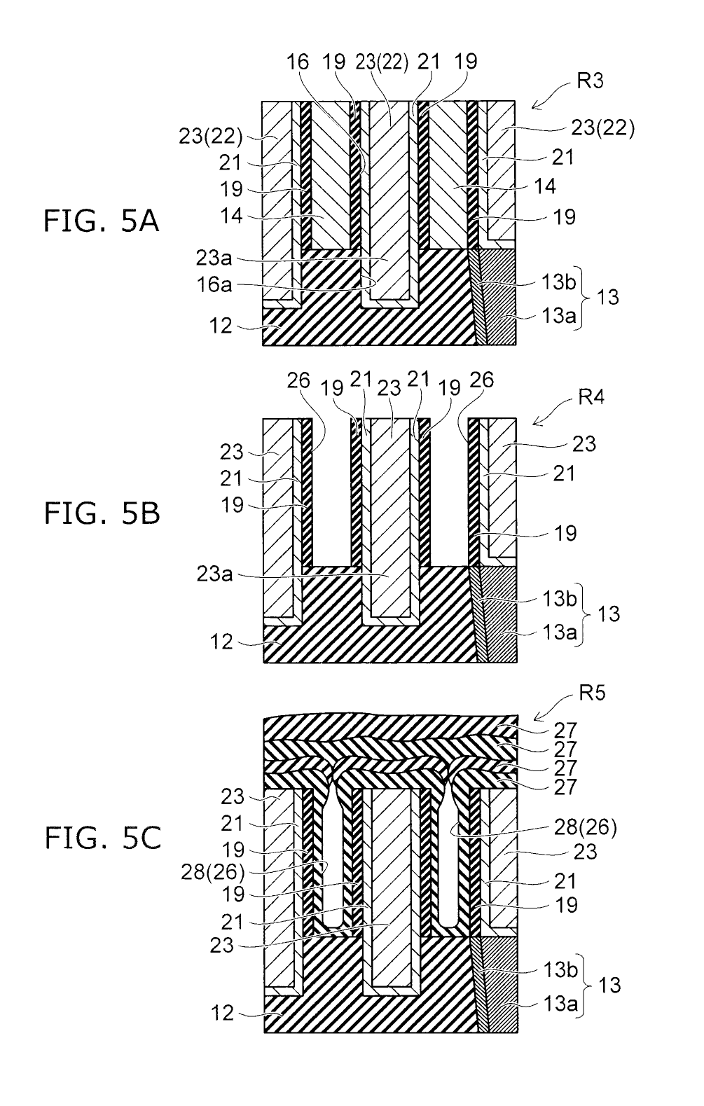

FIGS. 4A to 4C and FIGS. 5A to 5C are partially-enlarged cross-sectional views showing the method for manufacturing the integrated circuit device according to the embodiment.

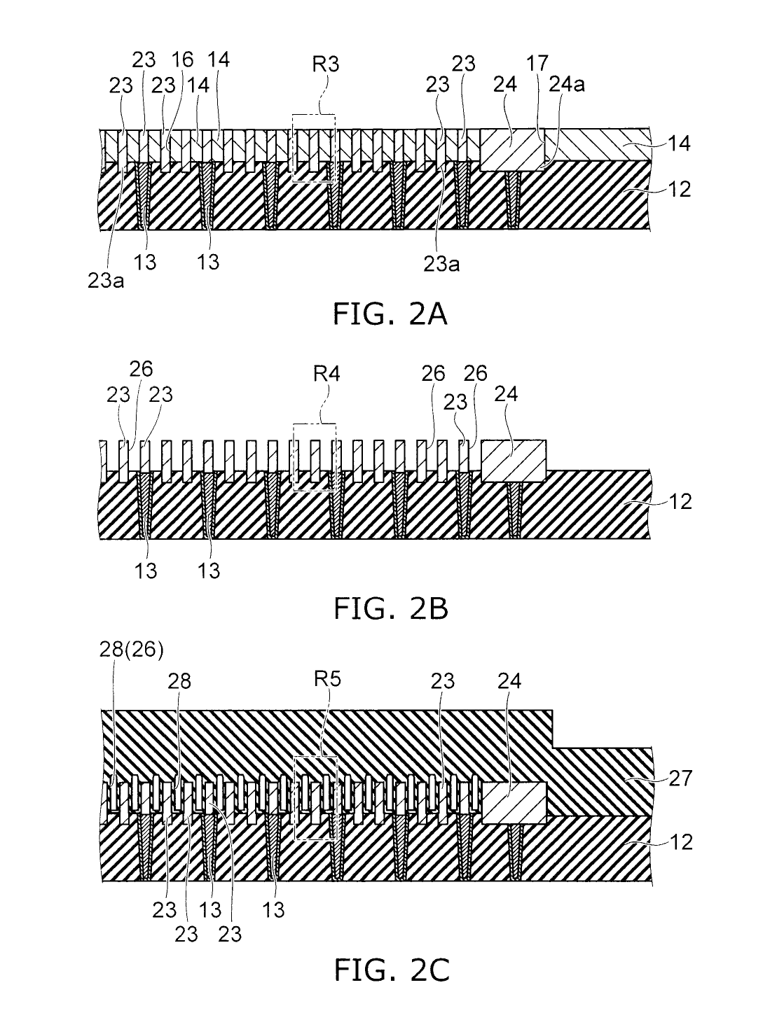

FIGS. 4A and 4B correspond to region R1 of FIG. 1B; FIG. 4C corresponds to region R2 of FIG. 1C; FIG. 5A corresponds to region R3 of FIG. 2A; FIG. 5B corresponds to region R4 of FIG. 2B; and FIG. 5C corresponds to region R5 of FIG. 2C.

First, the method for manufacturing the integrated circuit device according to the embodiment will be described.

The integrated circuit device according to the embodiment is, for example, a semiconductor integrated circuit device, e.g., NAND flash memory.

As shown in FIG. 1A, an insulative silicon oxide film 12 is formed on a silicon substrate (not shown); and multiple contacts 13 are formed inside the silicon oxide film 12. In the contacts 13, barrier metal layers 13b are formed on the side surfaces of main body portions 13a made of, for example, copper (Cu) or tungsten (W). The lower end portions of the contacts 13 are connected to a silicon substrate (not shown) or interconnects (not shown) of lower layers. Then, an amorphous silicon film 14 is formed on the silicon oxide film 12. Continuing, a mask pattern 15 is formed on the amorphous silicon film 14. The mask pattern 15 is, for example, a single-layer silicon oxide layer or a multilayered film including a silicon oxide layer and is patterned into a line-and-space configuration. In other words, multiple trenches 15a are made in the mask pattern 15. A wide trench 15b may be made in the mask pattern 15. The wide trench 15b extends in the same direction as the trenches 15a and is wider than the trenches 15a.

Then, as shown in FIG. 1B and FIG. 4A, etching of the amorphous silicon film 14 is performed using the mask pattern 15 as a mask. Namely, anisotropic etching such as, for example, RIE (Reactive Ion Etching), etc., is performed at conditions such that the etching rate of silicon is higher than the etching rate of silicon oxide. Thereby, the amorphous silicon film 14 is patterned to make trenches 16 in the regions directly under the trenches 15a to pierce the amorphous silicon film 14 and to make a wide trench 17 in the region directly under the wide trench 15b to pierce the amorphous silicon film 14.

Continuing, etching of the silicon oxide film 12 is performed using the patterned amorphous silicon film 14 as a mask. Namely, anisotropic etching is performed at conditions such that the etching rate of silicon oxide is higher than the etching rate of silicon. Thereby, lower end portions 16a of the trenches 16 and a lower end portion 17a of the wide trench 17 enter the upper layer portion of the silicon oxide film 12. Then, if the mask pattern 15 remains at this time, the mask pattern 15 is removed.

Then, as shown in FIG. 4B, oxidation treatment of the amorphous silicon film 14 patterned into the line-and-space configuration is performed. Thereby, a thin silicon oxide layer 19 of, for example, about one monolayer is formed on the exposed surfaces of the amorphous silicon film 14, i.e., the side surfaces and upper surface of each pattern portion. Or, the thin silicon oxide layer 19 of, for example, about one monolayer is formed on the side surfaces of each of the trenches 16 made in the amorphous silicon film 14 by depositing a thin silicon oxide film on the amorphous silicon film 14 patterned into the line-and-space configuration and on the silicon oxide film 12 exposed at the trench bottoms and by subsequently performing etch-back.

Continuing, a barrier metal layer 21 is formed as shown in FIG. 1C and FIG. 4C. The barrier metal layer 21 is formed by, for example, depositing a conductive material such as titanium (Ti), tantalum (Ta), tantalum nitride (TaN), etc., by PVD (Physical Vapor Deposition), CVD (Chemical Vapor Deposition), ALD (Atomic Layer Deposition), etc. Then, a metal material, e.g., copper (Cu), is deposited by, for example, plating, PVD, etc. Thereby, a metal film 22 is formed. The metal material is filled into the trenches 16 and into the wide trench 17.

Then, as shown in FIG. 2A and FIG. 5A, planarization such as CMP (Chemical Mechanical Polishing), etc., of the metal film 22 is performed using the amorphous silicon film 14 as a stopper. Thereby, the upper surface of the amorphous silicon film 14 is exposed; interconnects 23 are formed of the metal film 22 remaining inside the trenches 16; and a wide interconnect 24 is formed of the metal film 22 remaining inside the wide trench 17. The interconnects 23 and the wide interconnect 24 are made of copper; and the barrier metal layer 21 is formed on the side surfaces and lower surfaces of the interconnects 23 and the wide interconnect 24. Lower end portions 23a of the interconnects 23 and a lower end portion 24a of the wide interconnect 24 are filled into the upper layer portion of the silicon oxide film 12.

Continuing as shown in FIG. 2B and FIG. 5B, the amorphous silicon film 14 is removed by, for example, performing wet etching using an aqueous solution including choline as the etchant. Thereby, gaps 26 are made between the interconnects 23 and between the wide interconnect 24 and the interconnects 23. The silicon oxide layer 19 covers the barrier metal layer 21 on the side surfaces of the interconnects 23 and the wide interconnect 24.

Then, as shown in FIG. 2C and FIG. 5C, a capping film 27 made of silicon carbonitride (SiCN), silicon nitride (SiN), silicon carbide film (SiC), etc., is deposited by, for example, plasma CVD, etc. Thereby, the capping film 27 is formed above the interconnects 23 and the wide interconnect 24. The deposition of the capping film 27 is schematically illustrated as multiple layers in FIG. 5C. By depositing the insulating material described above at conditions at which the coverage is poor, the portions of the capping film 27 adhered to the upper end portions of the side surfaces of the gaps 26 are thicker than the other portions and protrude in eave-like configurations. Thereby, the insulating material is further adhered to the upper end portions of the portions protruding in the eave-like configurations. By repeating, the capping film 27 becomes a continuous film above the gaps 26 without the gaps 26 being completely filled; and the gaps 26 are sealed. Then, the remaining portion of the gaps 26 are used as air gaps 28. The capping film 27 is formed thinly at the bottoms and sides of the air gaps 28; and the upper end portions of the air gaps 28 are positioned to be higher than the upper end portions of the interconnects 23 and the wide interconnect 24.

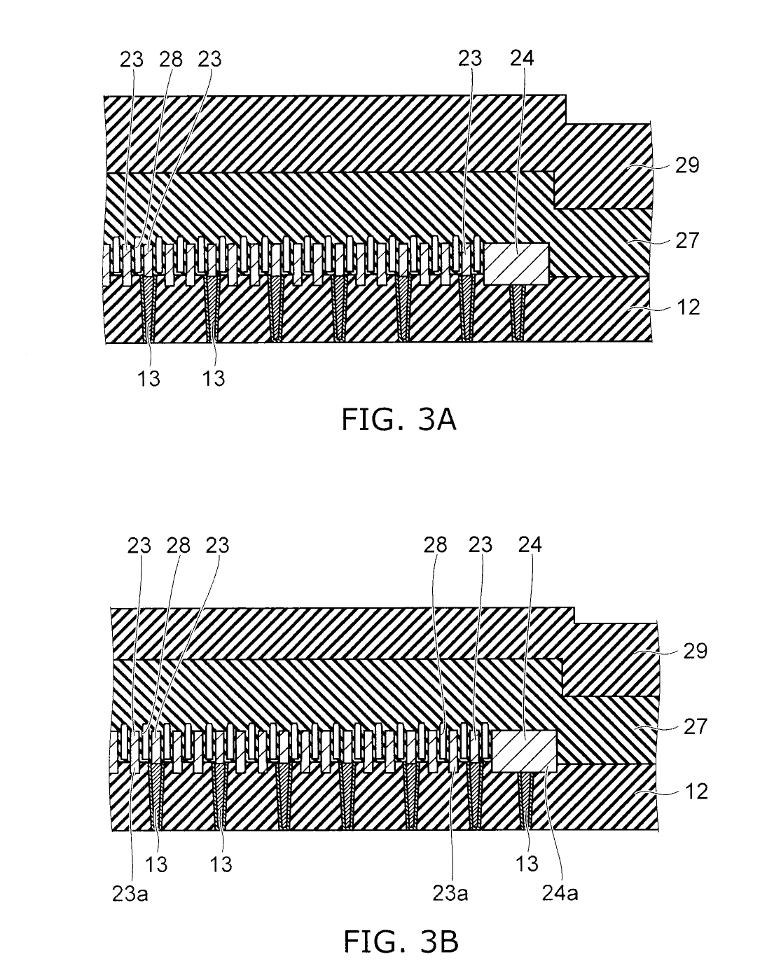

Continuing as shown in FIG. 3A, a silicon oxide film 29 is formed on the capping film 27. At this time, the upper surface of the portion of the silicon oxide film 29 positioned in the region where the interconnects 23 and the wide interconnect 24 are formed is higher than the upper surface of the portion of the silicon oxide film 29 positioned in the region where the interconnects 23 and the wide interconnect 24 are not formed; and a difference in levels is formed between the two regions.

Then, as shown in FIG. 3B, planarization of the upper surface of the silicon oxide film 29 is performed. Thereby, the difference in levels described above is reduced. Then, interconnects of upper layers, etc. (not shown) are formed on the silicon oxide film 29. Thus, the integrated circuit device according to the embodiment is manufactured.

The configuration of the integrated circuit device according to the embodiment manufactured as described above will now be described.

In the integrated circuit device according to the embodiment as shown in FIG. 3B and FIG. 5C, a silicon substrate (not shown) is provided; and the silicon oxide film 12 is provided on the silicon substrate. The multiple contacts 13 are formed inside the silicon oxide film 12. The lower ends of the contacts 13 are connected to the silicon substrate or the interconnects (not shown) of the lower layers. The multiple interconnects 23 and the wide interconnect 24 that extend in one direction are provided on the silicon oxide film 12. The interconnects 23 and the wide interconnect 24 are formed of, for example, copper (Cu). The lower end portions 23a of the interconnects 23 and the lower end portion 24a of the wide interconnect 24 are disposed inside the upper layer portion of the silicon oxide film 12. The interconnects 23 and the wide interconnect 24 are connected to the contacts 13.

The barrier metal layer 21 made of, for example, titanium (Ti), tantalum (Ta), tantalum nitride (TaN), etc., is formed on the lower surfaces and side surfaces of the interconnects 23 and the wide interconnect 24. A thin silicon oxide layer 19 of, for example, about one monolayer exists on the side surface of the barrier metal layer 21. The capping film 27 made of, for example, silicon carbonitride (SiCN), silicon nitride (SiN), silicon carbide (SiC), etc., is formed on the interconnects 23 and the wide interconnect 24; and the silicon oxide film 29 is formed on the capping film 27. Then, the air gaps 28 are made between the interconnects 23. The outer walls around the air gaps 28 are formed of the capping film 27; and the silicon oxide layer 19 is disposed between the capping film 27 and the barrier metal layer 21.

Effects of the embodiment will now be described.

In the embodiment, the amorphous silicon film 14 is formed on the silicon oxide film 12. Because the etching selectivity can be high between silicon and silicon oxide, the etching rate is not easily affected by the widths of the trenches. As a result, the depths of the trenches 16 and the wide trench 17 can be made to be uniform when making the trenches 16 and the wide trench 17 in the amorphous silicon film 14 in the etching process shown in FIG. 1B; and the thicknesses of the interconnects 23 and the wide interconnect 24 can be made to be uniform in the process shown in FIG. 2A. Also, when the amorphous silicon film 14 is removed in the process shown in FIG. 2B, the silicon oxide film 12 which is the foundation is not etched much. Therefore, the amorphous silicon film 14 does not remain; and the depths of the gaps 26 can be made to be uniform.

In the embodiment, the amorphous silicon film 14 is used as a mask when etching the silicon oxide film 12 in the process shown in FIG. 1B; and the amorphous silicon film 14 is used as a mold when forming the interconnects 23, etc., in the process shown in FIG. 1C and FIG. 2A. Thus, in the embodiment, because the amorphous silicon film 14 can have two functions, the number of films that are formed can be reduced; and the productivity can be increased. Although the amorphous silicon film 14 is a semiconductor and not an insulator, there is no risk of shorts between the interconnects 23 because the amorphous silicon film 14 is removed completely in the process shown in FIG. 2B.

In the embodiment, the lower end portions 16a of the trenches 16 and the lower end portion 17a of the wide trench 17 are made to enter the silicon oxide film 12 in the process shown in FIG. 1B. Accordingly, the lower end portions 23a of the interconnects 23 and the lower end portion 24a of the wide interconnect 24 are filled into the silicon oxide film 12 when forming the interconnects 23 and the wide interconnect 24 in the process shown in FIG. 2A. Thereby, the interconnects 23 and the wide interconnect 24 can be prevented from detaching when removing the amorphous silicon film 14 in the process shown in FIG. 2B.

In the embodiment, the thin silicon oxide layer 19 is formed on the exposed surfaces of the amorphous silicon film 14 by performing oxidation treatment of the amorphous silicon film 14 or by thinly depositing silicon oxide in the process shown in FIG. 1B and FIG. 4B. Thereby, the adhesion between the barrier metal layer 21 and the amorphous silicon film 14 can be improved when forming the barrier metal layer 21 in the process shown in FIG. 1C and FIG. 4C. Also, the barrier metal layer 21 is covered with the silicon oxide layer 19 at the side surfaces of the gaps 26 when making the gaps 26 by removing the amorphous silicon film 14 in the process shown in FIG. 2B and FIG. 5B. As a result, the oxidization of the barrier metal layer 21 can be suppressed; and the conductivity of the interconnects 23 can be ensured. As a result, the air gaps can be made between the interconnects without degradation of the interconnect reliability which is evaluated by the inter-interconnect insulative characteristics (TDDB), the electromigration (EM) characteristics, etc.

### Second Embodiment

A second embodiment will now be described.

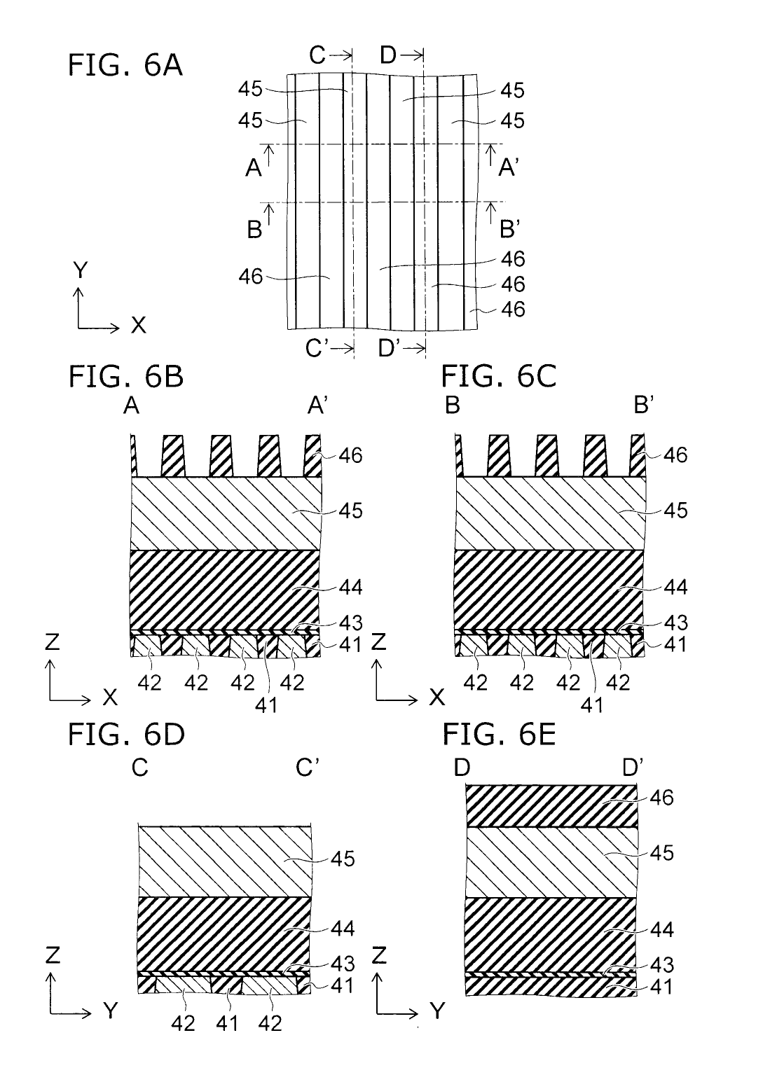

FIGS. 6A to 6E through FIGS. 13A to 13E show a method for manufacturing the integrated circuit device according to the embodiment.

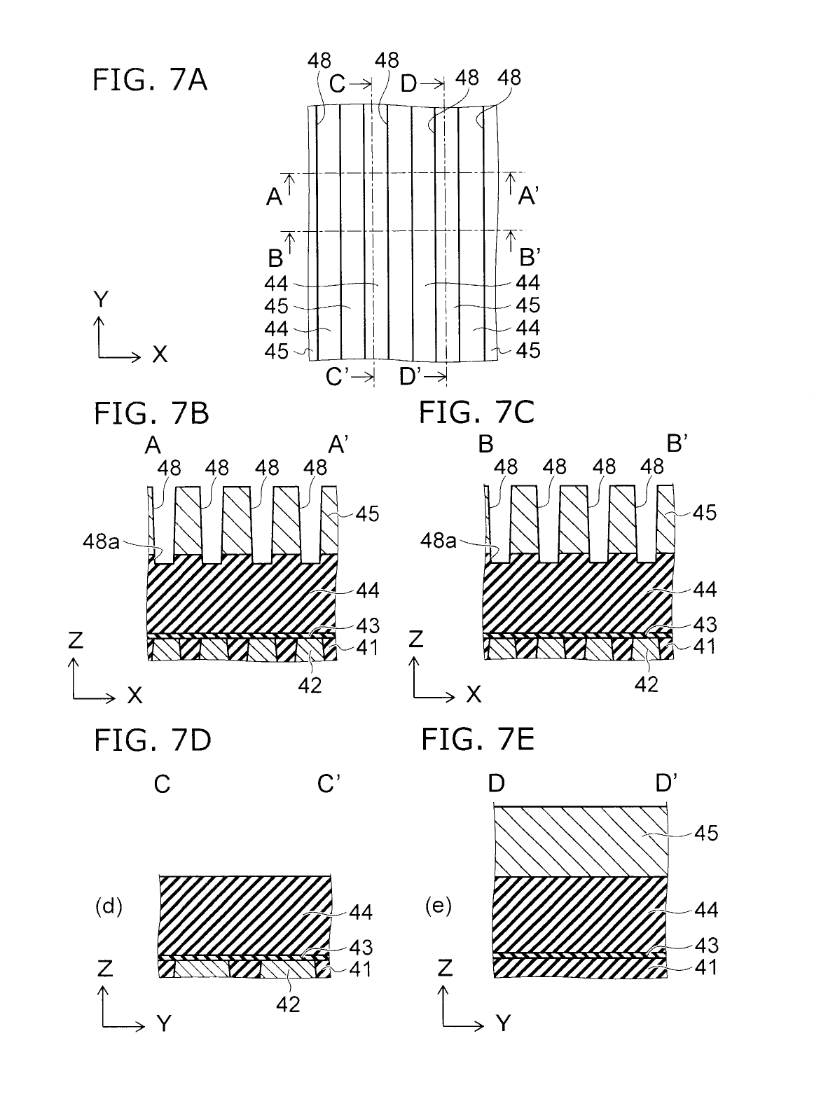

FIG. 6A is a plan view; FIG. 6B is a cross-sectional view along line A-A′ of FIG. 6A; FIG. 6C is a cross-sectional view along line B-B′ of FIG. 6A; FIG. 6D is a cross-sectional view along line C-C′ of FIG. 6A; and FIG. 6E is a cross-sectional view along line D-D′ of FIG. 6A. This is similar for FIGS. 7A to 7E through FIGS. 13A to 13E as well.

First, as shown in FIGS. 6A to 6E, a silicon oxide film 41 is formed on a silicon substrate (not shown); and interconnects or contacts 42 (hereinbelow, generally called the “contacts 42”) are formed inside the silicon oxide film 41. Then, a stopper layer 43 made of, for example, silicon nitride is formed; a silicon oxide film 44 is formed on the stopper layer 43; and an amorphous silicon film 45 is formed on the silicon oxide film 44. Then, a mask pattern 46 is formed in a line-and-space configuration extending in one direction by lithography. At this time, the mask pattern 46 has openings in the regions having line configurations including the regions directly above the contacts 42. The mask pattern 46 is, for example, a single-layer silicon oxide layer or a multilayered film including a silicon oxide layer.

For convenience of description in the embodiment, an XYZ orthogonal coordinate system is employed. Hereinbelow, a direction perpendicular to the upper surface of the silicon substrate is taken as a “Z-direction;” a direction in which the pattern portions of the mask pattern 46 extend is taken as a “Y-direction;” and a direction orthogonal to both the Z-direction and the Y-direction is taken as an “X-direction.”

Then, as shown in FIGS. 7A to 7E, etching of the amorphous silicon film 45 is performed using the mask pattern 46 (referring to FIGS. 6A to 6E) as a mask. Namely, anisotropic etching such as RIE, etc., is performed at conditions such that the etching rate of silicon is higher than the etching rate of silicon oxide. Thereby, multiple trenches 48 are made in the amorphous silicon film 45 to extend in the Y-direction and pierce the amorphous silicon film 45.

Continuing, etching of the silicon oxide film 44 is performed using the patterned amorphous silicon film 45 as a mask. Namely, anisotropic etching such as RIE, etc., is performed at conditions such that the etching rate of silicon oxide is higher than the etching rate of silicon. Thereby, lower end portions 48a of the trenches 48 enter the upper layer portion of the silicon oxide film 44. Subsequently, the mask pattern 46 is removed.

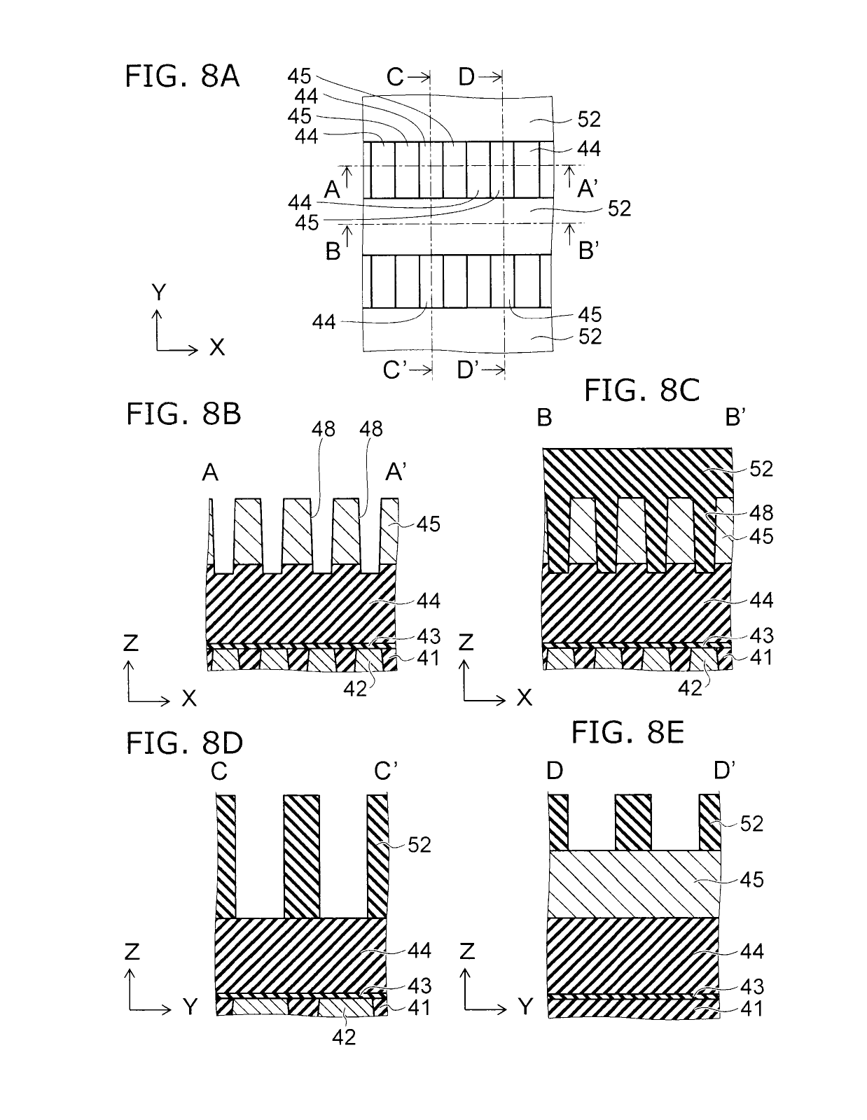

Then, as shown in FIGS. 8A to 8E, a mask pattern 52 is formed on the amorphous silicon film 45. For example, the mask pattern 52 is a single-layer resist layer or a multilayered film including a resist layer. A pattern having a line-and-space configuration extending in the X-direction is formed in the mask pattern 52. FIGS. 8A to BE show the case where the mask pattern 52 is a single-layer film. In such a case, there are openings in the regions of the mask pattern 52 having line configurations including the regions directly above the contacts 42.

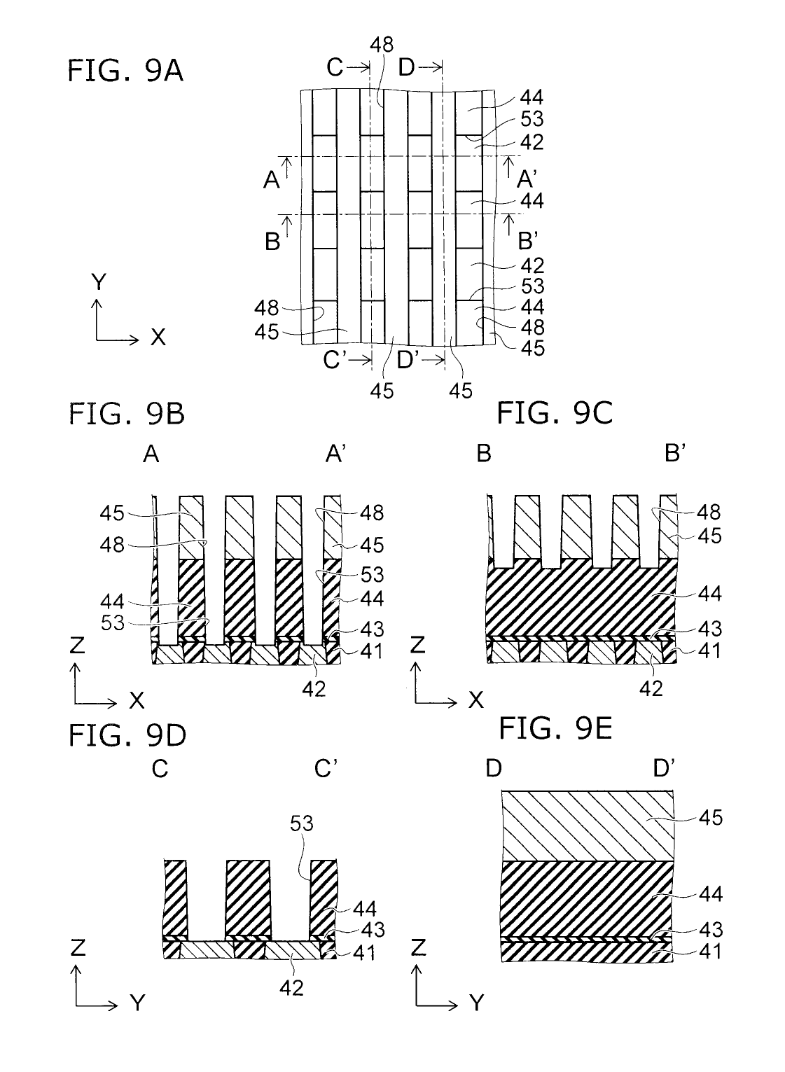

Continuing as shown in FIGS. 9A to 9E, etching of the silicon oxide film 44 is performed using the mask pattern 52 (referring to FIGS. 8A to 8E) and the patterned amorphous silicon film 45 as a mask. Namely, anisotropic etching such as RIE, etc., is performed at conditions such that the etching rate of silicon oxide is higher than the etching rate of silicon. At this time, because the configuration of the mask pattern 52 is a line-and-space configuration extending in the X-direction and the configuration of the amorphous silicon film 45 is a line-and-space configuration extending in the Y-direction, the mask pattern 52 and the amorphous silicon film 45 form a mask having a lattice configuration extending in the X-direction and the Y-direction as viewed from above (the Z-direction). Accordingly, by this etching, the portion of the silicon oxide film 44 having the lattice configuration remains; and the portion of the silicon oxide film 44 having the dot configuration arranged in the matrix configuration is removed.

As a result, multiple via holes 53 are made in a matrix configuration in the silicon oxide film 44 in the regions directly above the contacts 42. The configuration of each of the via holes 53 is a rectangular configuration as viewed from above.

Then, the mask pattern 52 is removed. Thereby, the trenches 48 are exposed again.

Continuing, the stopper layer 43 is etched using the amorphous silicon film 45 as a mask. Thereby, the contacts 42 are exposed at the bottom surfaces of the via holes 53.

Subsequently, similarly to the first embodiment described above, the thin silicon oxide layer 19 (referring to FIG. 4B) may be formed on the exposed surfaces of the amorphous silicon film 45 by performing oxidation treatment of the amorphous silicon film 45 or by thinly depositing silicon oxide and performing etch-back.

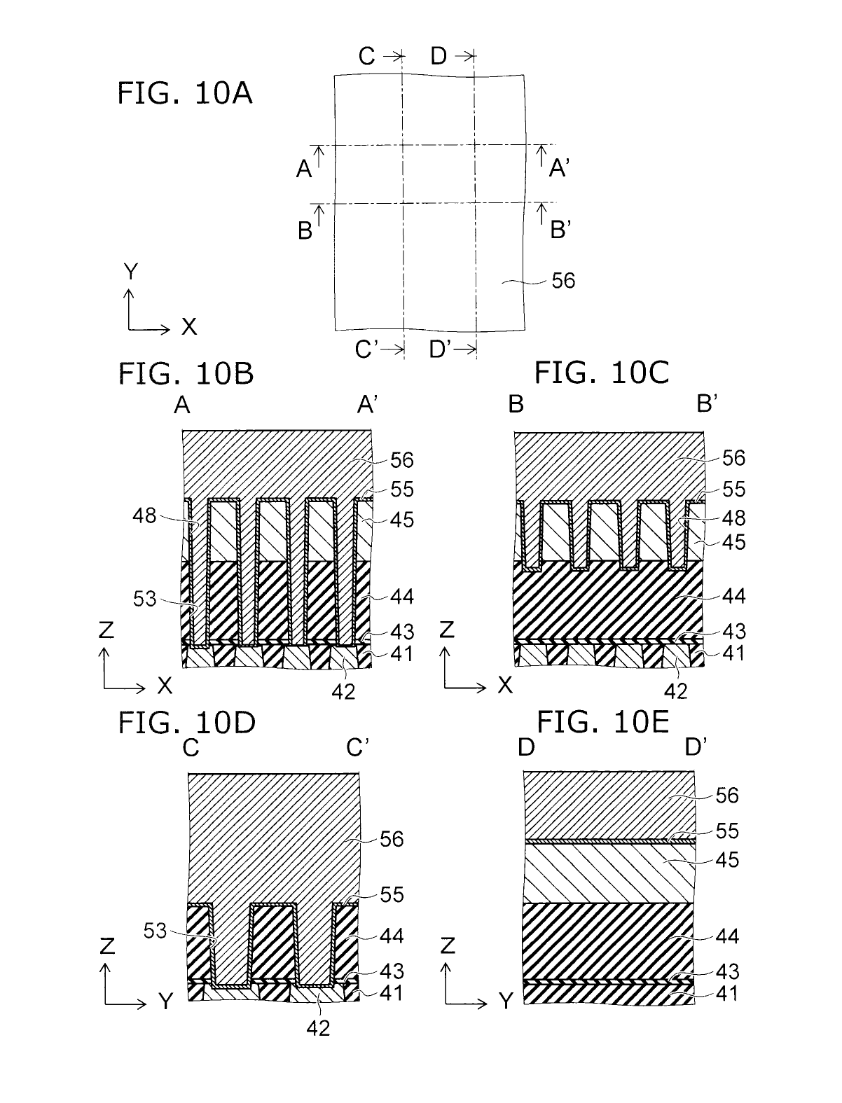

Then, as shown in FIGS. 10A to 10E, a barrier metal layer 55 is formed by, for example, depositing a conductive material such as titanium (Ti), tantalum (Ta), tantalum nitride (TaN), etc., by PVD, CVD, ALD, etc. Then, a metal film 56 is formed by depositing a metal material, e.g., copper (Cu), by plating, PVD, etc. The barrier metal layer 55 and the metal film 56 are filled into the via holes 53 and into the trenches 48.

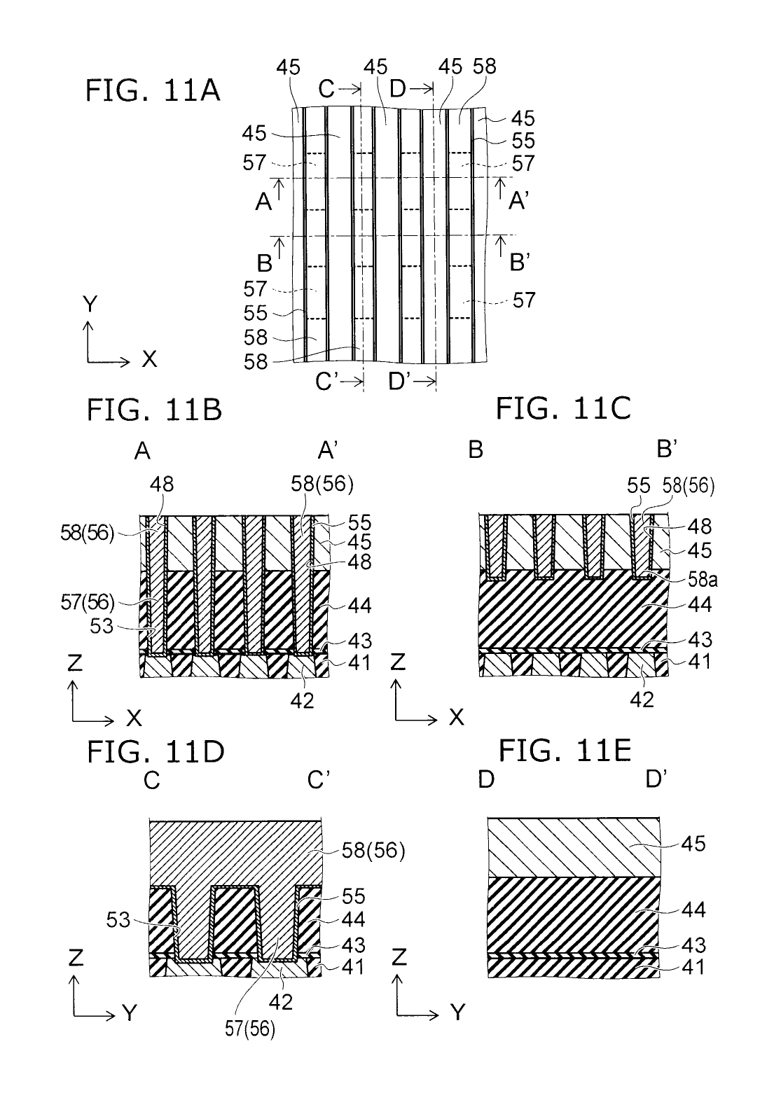

Continuing as shown in FIGS. 11A to 11E, planarization such as CMP, etc., of the upper surface of the metal film 56 is performed using the amorphous silicon film 45 as a stopper. Thereby, the portion of the metal film 56 that is positioned higher than the amorphous silicon film 45 is removed. As a result, vias 57 are formed of the metal film 56 remaining inside the via holes 53; and interconnects 58 are formed of the metal film 56 remaining inside the trenches 48. The vias 57 and the interconnects 58 are formed as one body. Lower end portions 58a of the interconnects 58 are disposed inside the upper layer portion of the silicon oxide film 44.

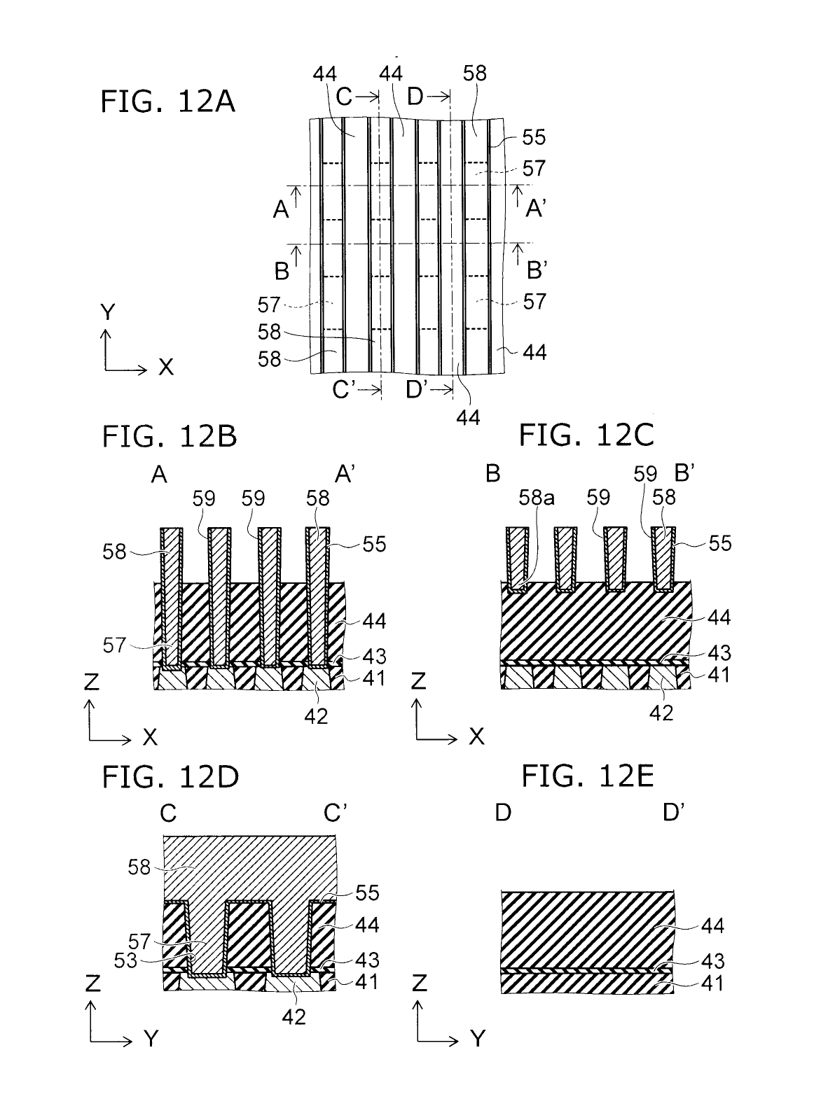

Then, as shown in FIGS. 12A to 12E, the amorphous silicon film 45 is removed by, for example, performing wet etching using an aqueous solution including choline as the etchant. Thereby, gaps 59 are made between the portions of the interconnects 58 other than the lower end portions 58a. In the case where the silicon oxide layer is formed on the exposed surfaces of the amorphous silicon film 45 in the process shown in FIGS. 9A to 9E, the silicon oxide layer is exposed at the side surfaces of the gaps 59.

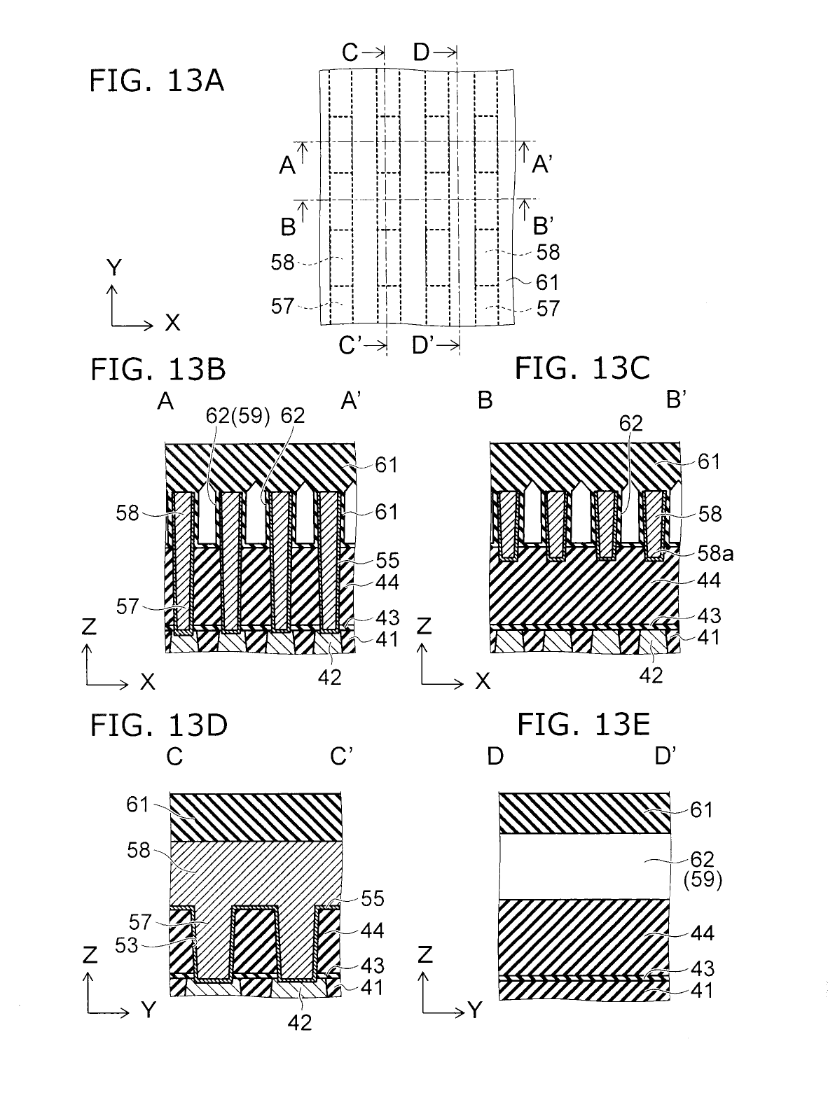

Continuing as shown in FIGS. 13A to 13E, an insulating material of, for example, silicon carbonitride (SiCN), silicon nitride (SiN), silicon carbide (SiC), etc., is deposited by plasma CVD, etc. Thereby, a capping film 61 is formed above the multiple interconnects 58. At this time, similarly to the first embodiment (referring to FIG. 5C) described above, by depositing an insulating material such as silicon carbonitride, etc., at conditions such that the coverage is poor, the capping film 61 adheres over and seals the upper end portions of the gaps 59 without filling the gaps 59. As a result, the gaps 59 become air gaps 62 after the capping film 61 is formed. The capping film 61 is thinly formed on the lower surfaces and side surfaces of the air gaps 62. Also, the upper end portions of the air gaps 62 are positioned to be higher than the upper end portions of the interconnects 58. Then, the interconnects, the inter-layer insulating films, etc. (not shown) of the upper layers are formed on the capping film 61 by normal methods. Thus, the integrated circuit device according to the embodiment is manufactured.

The configuration of the integrated circuit device according to the embodiment manufactured as described above will now be described.

In the integrated circuit device according to the embodiment as shown in FIGS. 13A to 13E, the silicon oxide film 41 is provided on a silicon substrate (not shown); and the contacts 42 (or interconnects) are formed inside the silicon oxide film 41. The silicon oxide film 44 is provided on the silicon oxide film 41 with the stopper layer 43 interposed. Then, the vias 57 are multiply provided inside the silicon oxide film 44 and are connected to the contacts 42. The interconnects 58 that extend in the Y-direction are multiply provided on the silicon oxide film 44 and are connected to the vias 57. The vias 57 and the interconnects 58 are formed as integral bodies. The barrier metal layer 55 made of, for example, titanium (Ti), tantalum (Ta), tantalum nitride (TaN), etc., is formed on the lower surfaces and side surfaces of the structural bodies made of the vias 57 and the interconnects 58.

The capping film 61 is provided above the multiple interconnects 58. The lower end portions 58a of the interconnects 58 are positioned inside the upper layer portion of the silicon oxide film 44; and the air gaps 62 are made between the portions of the interconnects 58 other than the lower end portions 58a. The outer walls around the air gaps 62 are covered with the thin capping film 61; and the upper end portions of the air gaps 62 are positioned to be higher than the upper end portions of the interconnects 58. The thin silicon oxide layer 19 (referring to FIG. 4B) of, for example, about one monolayer is formed between the barrier metal layer 55 and the capping film 61.

Effects of the embodiment will now be described.

In the embodiment, the amorphous silicon film 45 that is patterned in a line-and-space configuration extending in the Y-direction is formed on the silicon oxide film 44; the mask pattern 52 having a line-and-space configuration extending in the X-direction is formed on the amorphous silicon film 45; and the via holes 53 are formed inside the silicon oxide film 44 by performing etching using the amorphous silicon film 45 and the mask pattern 52 as a mask in the process shown in FIGS. 9A to 9E. Thereby, the fine via holes 53 having a high arrangement density can be made.

In the embodiment, the vias 57 and the interconnects 58 can be formed self-aligningly because the via holes 53 are made using the amorphous silicon film 45 in which the trenches 48 having line configurations are made as a mask, the vias 57 are formed inside the via holes 53, and the interconnects 58 are formed inside the trenches 48. Thereby, it is possible to suppress the alignment shift of the vias 57 with respect to the interconnects 58; and breakdown voltage degradation and shorts between the vias 57 and between the interconnects 58 can be suppressed.

In the embodiment, the amorphous silicon film 45 is used as a mask for making the via holes 53 and as a mold when forming the interconnects 58. Thus, because one film has two functions, the number of processes can be reduced. Accordingly, the productivity of the method for manufacturing the integrated circuit device according to the embodiment is high.

Otherwise, the effects of the embodiment are similar to those of the first embodiment described above.

Namely, the trenches 48 having uniform depths can be made in the amorphous silicon film 45 in the process shown in FIGS. 7A to 7E because the etching selectivity between silicon and silicon oxide can be high; and accordingly, the interconnects 58 can be formed to have uniform thicknesses in the processes shown in FIGS. 11A to 11E. Also, because the amorphous silicon film 45 can be removed with high precision in the processes shown in FIGS. 12A to 12E, the gaps 59 can be made to have uniform depths.

By the lower end portions 48a of the trenches 48 entering the silicon oxide film 44 in the process shown in FIGS. 7A to 7E, the lower end portions 58a of the interconnects 58 can be filled into the silicon oxide film 44 in the process shown in FIGS. 11A to 11E. Thereby, when the amorphous silicon film 45 is removed in the process shown in FIGS. 12A to 12E, the interconnects 58 can be prevented from detaching.

Further, if the thin silicon oxide layer 19 (referring to FIG. 4B) is formed by oxidation treatment of the amorphous silicon film 45 or by depositing silicon oxide and performing etch-back in the process shown in FIGS. 7A to 7E, the adhesion between the barrier metal layer 55 and the amorphous silicon film 45 can be higher when forming the barrier metal layer 55 in the process shown in FIGS. 10A to 10E. Also, oxidization of the barrier metal layer 55 can be suppressed because the barrier metal layer 55 at the side surfaces of the gaps 59 can be covered with the silicon oxide layer 19 when the gaps 59 are made by removing the amorphous silicon film 45 in the process shown in FIGS. 12A to 12E. As a result, the air gaps 62 can be made between the interconnects 58 without degradation of the interconnect reliability such as the inter-interconnect insulative characteristics (TDDB), the electromigration (EM) characteristics, etc.

### Third Embodiment

A third embodiment will now be described.

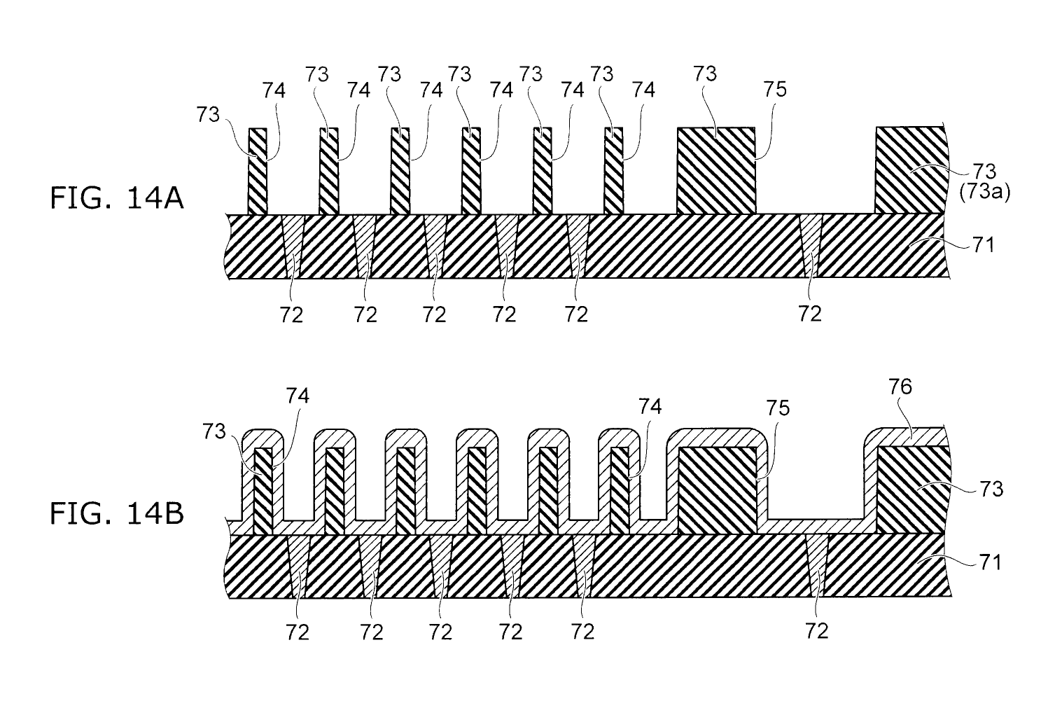

FIG. 14A to FIG. 17B are cross-sectional views showing a method for manufacturing an integrated circuit device according to the embodiment.

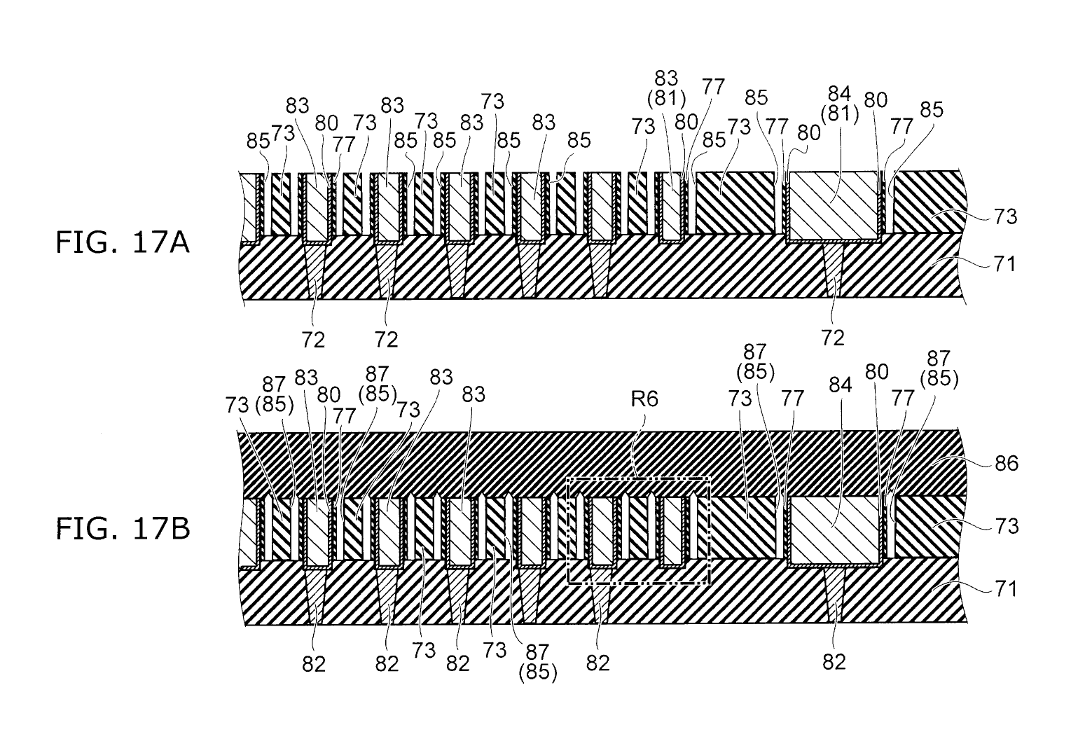

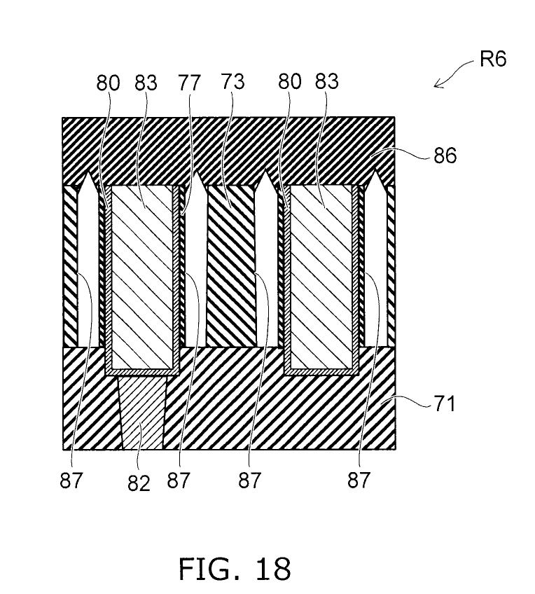

FIG. 18 is a partially-enlarged cross-sectional view showing region R6 of FIG. 17B.

In the embodiment, instead of forming the entire mold of the interconnects of amorphous silicon as in the first embodiment described above, the core unit of the mold is formed of silicon oxide; the side walls of the mold are formed of amorphous silicon; and only the amorphous silicon is removed after the interconnect formation.

First, as shown in FIG. 14A, a silicon oxide film 71 made of silicon oxide (SiO₂) is formed on a silicon substrate (not shown); and multiple contacts 72 made of, for example, a metal such as copper (Cu), tungsten (W), etc., are formed inside the silicon oxide film 71. Then, a silicon oxide film 73a made of, for example, silicon oxide is formed on the silicon oxide film 71 by CVD using TEOS (tetraethoxysilane (Si(OC₂H₅)₄)) as the source. Then, a mask pattern (not shown) having a line-and-space configuration is formed on the silicon oxide film 73a. Then, etching such as RIE, etc., of the silicon oxide film 73a is performed using the mask pattern as a mask. Thereby, trenches 74 and a wide trench 75 are made by selectively removing the regions of the silicon oxide film 73a including the regions directly above the contacts 72. The wide trench 75 extends in the same direction as the trenches 74 and is wider than the trenches 74. The remaining portions of the silicon oxide film 73a are used as silicon oxide members 73 extending in one direction. Subsequently, the mask pattern is removed.

Then, as shown in FIG. 14B, an amorphous silicon film 76 is formed by depositing amorphous silicon on the entire surface. The film thickness of the amorphous silicon film 76 is substantially uniform. The amorphous silicon film 76 is formed not only on the upper surfaces of the silicon oxide members 73 but also on the bottom surfaces and side surfaces of the trenches 74 and the wide trench 75.

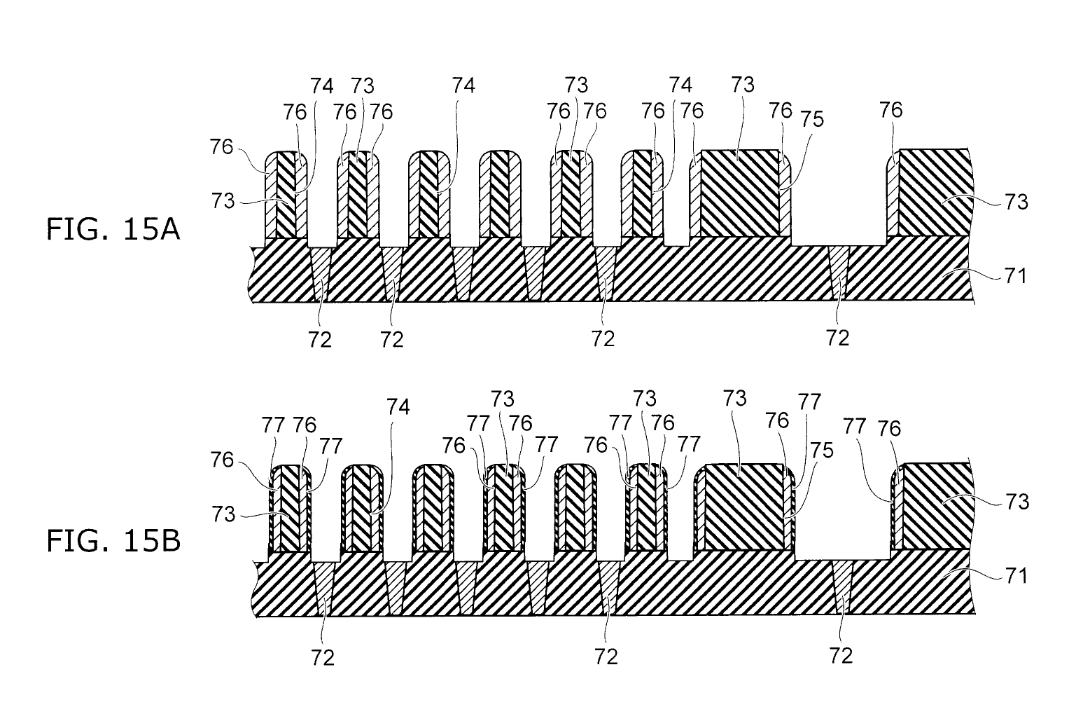

Continuing as shown in FIG. 15A, etch-back of the amorphous silicon film 76 is performed. Thereby, the portion of the amorphous silicon film 76 formed on the upper surfaces of the silicon oxide members 73 and the portion of the amorphous silicon film 76 formed on the bottom surfaces of the trenches 74 and the wide trench 75 are removed; and the portion of the amorphous silicon film 76 formed on the side surfaces of the trenches 74 and the wide trench 75 remains. As a result, a pattern having a line-and-space configuration is formed in which the silicon oxide members 73 are core members and the amorphous silicon films 76 are the side walls. Also, the upper layer portion of the silicon oxide film 71 and the upper end portions of the contacts 72 are removed at the bottom portions of the trenches 74 and the wide trench 75 by etching.

Then, as shown in FIG. 15B, oxidation treatment of the amorphous silicon films 76 is performed. Or, silicon oxide is thinly deposited on the entire surface; and etch-back is performed subsequently. Thereby, a thin silicon oxide layer 77 of, for example, about one monolayer is formed on the exposed surfaces of the amorphous silicon film 76.

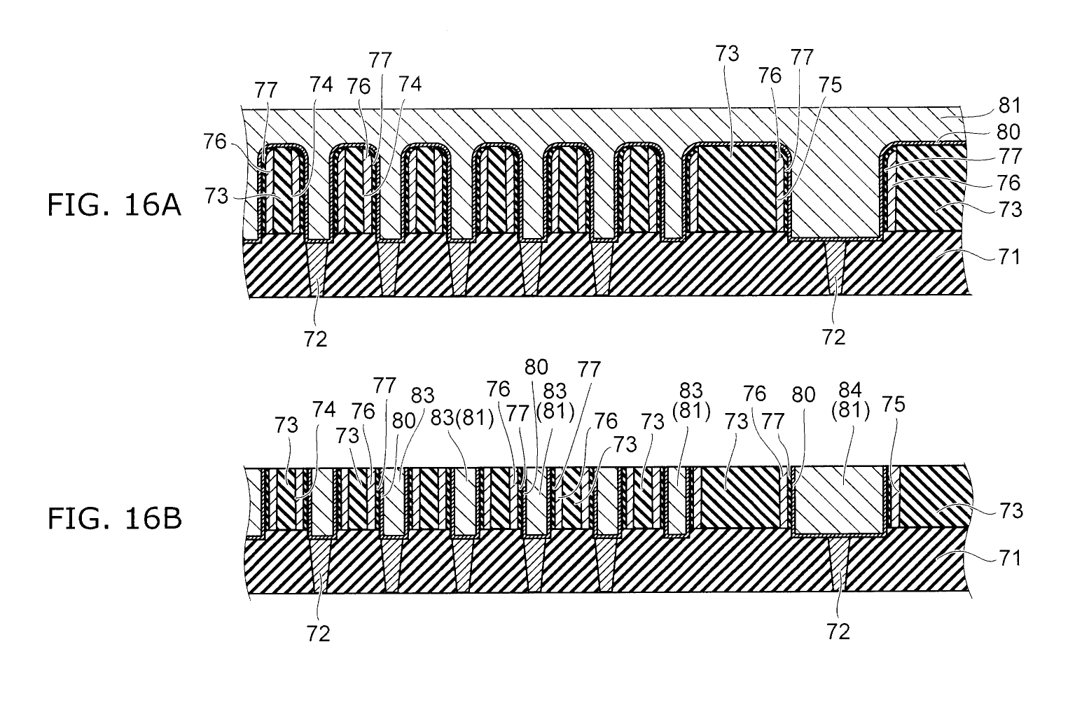

Continuing as shown in FIG. 16A, a barrier metal layer 80 is formed by, for example, depositing a conductive material such as titanium (Ti), tantalum (Ta), tantalum nitride (TaN), etc., by PVD, CVD, ALD, etc. Then, a metal film 81 is formed by, for example, depositing a metal material, e.g., copper (Cu), by plating, PVD, etc. The barrier metal layer 80 and the metal film 81 also are formed inside the trenches 74, inside the wide trench 75, and on the oxidized surfaces of the amorphous silicon film 76, i.e., on the silicon oxide layer 77.

Then, as shown in FIG. 16B, planarization of the entire surface is performed by CMP. Thereby, the portions of the metal film 81 and the barrier metal layer 80 deposited on the silicon oxide members 73 are removed; and subsequently, the upper portions of the silicon oxide members 73 are removed together with the amorphous silicon film 76 and the silicon oxide layer 77 formed on the side surfaces of the silicon oxide members 73. As a result, the portion of the metal film 81 filled into the trenches 74 becomes interconnects 83; and the portion of the metal film 81 filled into the wide trench 75 becomes a wide interconnect 84.

Continuing as shown in FIG. 17A, the amorphous silicon film 76 is removed by, for example, wet etching using an aqueous solution including choline as the etchant. Thereby, gaps 85 are made between the silicon oxide members 73 and the silicon oxide layer 77. In other words, the members are arranged between the mutually-adjacent interconnects 83 in the order of (interconnect 83-barrier metal layer 80-silicon oxide layer 77-gap 85-silicon oxide member 73-gap 85-silicon oxide layer 77-barrier metal layer 80-interconnect 83). Because the film thickness of the amorphous silicon film 76 is substantially uniform at this time, the widths of the gaps 85 are substantially constant and do not depend on the widths of the trenches 74 and the wide trench 75. The surface of the barrier metal layer 80 on the gap 85 side is covered with the silicon oxide layer 77.

Then, as shown in FIG. 17B and FIG. 18, a capping film 86 is formed by, for example, depositing an insulating material such as silicon carbonitride (SiCN), silicon nitride (SiN), silicon carbide film (SiC), etc., by plasma CVD, etc. At this time, similarly to the first embodiment described above, the gaps 85 are not filled and become air gaps 87 by an insulating material being deposited at conditions such that the coverage is poor. At this time, there are cases where a portion of the capping film 86 enters the air gaps 87; and there are cases where a portion of the capping film 86 does not enter the air gaps 87. FIG. 17B and FIG. 18 show the case where the capping film 86 does not enter the air gaps 87. In the case where a portion of the capping film 86 enters the air gaps 87, similarly to the first embodiment (referring to FIG. 5C) described above, the capping film 86 is thinly formed on the inner surfaces of the air gaps 87. The upper ends of the air gaps 87 are positioned to be higher than the upper ends of the silicon oxide members 73, the interconnects 83, and the wide interconnect 84. Thus, the integrated circuit device according to the embodiment is manufactured.

The configuration of the integrated circuit device according to the embodiment manufactured as described above will now be described.

In the integrated circuit device according to the embodiment as shown in FIG. 17B and FIG. 18, a silicon substrate (not shown) is provided; and the silicon oxide film 71 is provided on the silicon substrate. The multiple contacts 72 are formed inside the silicon oxide film 71. The lower ends of the contacts 72 are connected to the silicon substrate or the interconnects (not shown) of the lower layers. The multiple interconnects 83 and the wide interconnect 84 that extend in one direction are provided on the silicon oxide film 71. The interconnects 83 and the wide interconnect 84 are formed of, for example, copper (Cu). The interconnects 83 and the wide interconnect 84 are connected to the contacts 72.

The barrier metal layer 80 made of, for example, titanium (Ti), tantalum (Ta), tantalum nitride (TaN), etc., is formed on the lower surfaces and side surfaces of the interconnects 83 and the wide interconnect 84. The thin silicon oxide layer 77 of, for example, about one monolayer exists on the side surface of the barrier metal layer 80.

The silicon oxide members 73 are provided between the mutually-adjacent interconnects 83 and between the wide interconnect 84 and the interconnects 83. The silicon oxide members 73 extend in the same direction as the interconnects 83 and the wide interconnect 84. The air gaps 87 are made between the silicon oxide members 73 and the interconnects 83 and between the silicon oxide members 73 and the wide interconnect 84.

The capping film 86 made of, for example, silicon carbonitride (SiCN), silicon nitride (SiN), silicon carbide (SiC), etc., is provided above the interconnects 83, the wide interconnect 84, the silicon oxide members 73, and the air gaps 87. A portion of the capping film 86 may be made thinly on the inner surfaces of the air gaps 87. In such a case, a portion of the capping film 86 is used as the outer walls around the air gaps 87. The upper ends of the air gaps 87 jut into the lower surface of the capping film 86 to be higher than the upper ends of the interconnects 83, the wide interconnect 84, and the silicon oxide members 73.

Effects of the embodiment will now be described.

In the embodiment, the silicon oxide members 73, the silicon oxide layers 77, and the amorphous silicon films 76 are polished after the metal film 81 and the barrier metal layer 80 are polished in the CMP process shown in FIG. 16B. At this time, the greater part of the materials to be polished is silicon oxide because the film thicknesses of the amorphous silicon films 76 are thinner than the widths of the silicon oxide members 73. Therefore, a conventional CMP process can be used to polish the silicon oxide.

According to the embodiment, the widths of the gaps 85 made in the wet etching process shown in FIG. 17A are equal to the film thicknesses of the amorphous silicon films 76 that are removed. Also, the widths of the gaps 85 are substantially uniform because the film thicknesses of the amorphous silicon films 76 are substantially uniform. Thus, because the widths of the gaps 85 can be substantially constant regardless of the widths of the interconnects 83 and the wide interconnect 84 and the spacing of the interconnects, the penetration of the capping film 86 into the gaps 85 in the formation process of the capping film 86 shown in FIG. 17B can be suppressed; and the upper surface of the capping film 86 can be formed to be flat. Further, the difference in levels that is formed on the upper surface of the capping film 86 at the boundary between the region where the interconnects 83 and the wide interconnect 84 are formed and the region where the interconnects 83 and the wide interconnect 84 are not formed can be suppressed. Thus, the planarization of the capping film 86 can be omitted because the upper surface of the capping film 86 can be formed to be flat.

According to the embodiment, for the mold of the interconnects 83 and the wide interconnect 84, the silicon oxide members 73 are used as the core members; and the amorphous silicon films 76 are used as the side walls. By using the silicon oxide members 73, cleaning is easy and dust and watermarks do not remain easily because silicon oxide is hydrophilic. Therefore, the integrated circuit device according to the embodiment is easy to manufacture.

According to the embodiment, the silicon oxide members 73 function as pillars for the air gaps 87 because the silicon oxide members 73 are provided between the mutually-adjacent interconnects 83 and the air gaps 87 are made on two sides of the silicon oxide members 73. As a result, the mechanical strength is higher for the integrated circuit device according to the embodiment than for the integrated circuit device according to the first embodiment described above.

On the other hand, the parasitic capacitance between the interconnects 23 can be reduced more effectively for the first embodiment described above than for the embodiment because one large air gap 28 is made between the interconnects 23 in the first embodiment.

Otherwise, the configuration, the manufacturing method, and the effects of the embodiment are similar to those of the first embodiment described above.

For example, by forming the thin silicon oxide layer 77 on the amorphous silicon film 76, the adhesion between the barrier metal layer 80 and the amorphous silicon film 76 can be higher in the process shown in FIG. 16A. Also, the oxidization of the barrier metal layer 80 can be suppressed because the surface of the barrier metal layer 80 on the gap 85 side can be covered with the silicon oxide layer 77 when making the gap 85 in the process shown in FIG. 17A. As a result, the air gap 87 can be made without degradation of the interconnect reliability such as the inter-interconnect insulative characteristics (TDDB), the electromigration (EM) characteristics, etc.

In the embodiment described above, a polysilicon film or an amorphous silicon film having a crystallized portion may be used instead of the amorphous silicon film. However, in the case where the silicon film is crystallized, the etching rate of the (111) plane of the silicon is slower when etching using the choline aqueous solution; and it is slightly more difficult to remove the silicon film uniformly. Therefore, it is favorable for the amorphous silicon film to be used if possible. Components other than silicon may be mixed into the amorphous silicon film. Further, a device other than NAND flash memory may be manufactured as the integrated circuit device.

According to the embodiments described above, an integrated circuit device and a method for manufacturing the integrated circuit device in which uniform interconnects and air gaps are made can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. An integrated circuit device, comprising:
a first insulating film;
a plurality of interconnects provided on the first insulating film to extend in a first direction;
a barrier metal layer provided on a side surface of the interconnects;
a silicon oxide layer provided on a side surface of the barrier metal layer; and
a second insulating film provided on the plurality of interconnects,
an air gap being made between the interconnects, and the silicon oxide layer being disposed between the air gap and the barrier metal layer.

2. The device according to claim 1, wherein a lower end portion of the interconnects is disposed in the first insulating film.

3. The device according to claim 1, further comprising a contact disposed below the interconnects, the contact being connected to the interconnects and being rectangular as viewed from above.

4. The device according to claim 1, wherein the first insulating film includes silicon oxide.

5. The device according to claim 1, wherein the second insulating film includes at least one type of material selected from the group consisting of silicon carbonitride, silicon nitride, and silicon carbide.

6. An integrated circuit device, comprising:
a first insulating film;
a plurality of interconnects provided on the first insulating film to extend in a first direction;
an insulating member provided between the interconnects to extend in the first direction; and
a second insulating film provided on the plurality of interconnects and on the insulating member,
an air gap being made between the insulating member and the interconnects.

7. The device according to claim 6, further comprising:
a barrier metal layer provided on a side surface of the interconnects; and
a silicon oxide layer provided on a side surface of the barrier metal layer,
the silicon oxide layer being disposed between the air gap and the barrier metal layer.

8. A method for manufacturing an integrated circuit device, comprising:
forming a silicon film on a first insulating film;
making a plurality of trenches to pierce the silicon film by etching the silicon film;
forming a plurality of interconnects by filling a metal material into the trenches;
removing the silicon film; and
forming a second insulating film on the plurality of interconnects without filling a gap between the interconnects.

9. The method according to claim 8, wherein the making of the trenches includes a lower end portion of the trenches entering an upper layer portion of the first insulating film.

10. The method according to claim 8, further comprising:
oxidizing an exposed surface of the silicon film which the trenches are made; and
forming a barrier metal layer on a side surface of the trenches,
the removing of the silicon film including removing the unoxidized portion of the silicon film while causing the oxidized portion of the silicon film to remain.

11. The method according to claim 8, further comprising:
depositing silicon oxide on the silicon film which the trenches are made;
performing etch-back of the deposited silicon oxide and causing the silicon oxide to remain on a side surface of the trenches; and
forming a barrier metal layer on the side surface of the trenches,
the removing of the silicon film including removing the silicon film while causing the silicon oxide to remain.

12. The method according to claim 8, wherein an amorphous silicon film is used as the silicon film.

13. The method according to claim 8, wherein the first insulating film includes silicon oxide.

14. The method according to claim 8, wherein the second insulating film includes at least one type of material selected from the group consisting of silicon carbonitride, silicon nitride, and silicon carbide.

15. A method for manufacturing an integrated circuit device, comprising:
forming a silicon film on a first insulating film;
forming a first mask pattern on the silicon film to extend in a first direction;
making a plurality of trenches extending in the first direction and piercing the silicon film by etching the silicon film using the first mask pattern as a mask;
forming a second mask pattern extending in a second direction intersecting the first direction;
making a hole inside the first insulating film by etching the first insulating film using the second mask pattern and the silicon film as a mask;
exposing the trenches by removing the second mask pattern;
forming a via inside the hole and forming a plurality of interconnects inside the plurality of trenches by filling a metal material into the hole and into the trenches;
removing the silicon film; and
forming a second insulating film on the plurality of interconnects without filling a gap between the interconnects.

16. A method for manufacturing an integrated circuit device, comprising:
forming a plurality of insulating members extending in one direction on a first insulating film;
forming a silicon film on a side surface of the insulating members;
forming an interconnect by filling a metal material between the insulating members and between the silicon film;
making a gap by removing the silicon film; and
forming a second insulating film on the interconnect and on the insulating members without filling the gap.

17. The method according to claim 16, further comprising:
oxidizing an exposed surface of the silicon film; and
forming a barrier metal layer on the oxidized surface of the silicon film,
the making of the gap including removing the unoxidized portion of the silicon film while causing the oxidized portion of the silicon film to remain.

18. The method according to claim 16, further comprising:
depositing silicon oxide on the silicon film;
performing etch-back of the deposited silicon oxide and causing the silicon oxide to remain on a side surface of the silicon film; and
forming a barrier metal layer on a layer made of the remaining silicon oxide,
the making of the gap including removing the silicon film while causing the silicon oxide to remain.

19. A method for manufacturing an integrated circuit device, comprising:
forming a first inter-layer film on an insulating film;
forming a first mask pattern on the first inter-layer film to extend in a first direction;
making a plurality of trenches extending in the first direction and piercing the first inter-layer film by etching the first inter-layer film using the first mask pattern as a mask;
forming a second mask pattern extending in a second direction intersecting the first direction;
making a hole in the insulating film by etching the insulating film using the second mask pattern and the first inter-layer film where the trenches are made as a mask; and
forming a via inside the hole and forming interconnects inside the trenches by filling a metal material into the hole and into the trenches.

20. The method according to claim 19, further comprising removing the first inter-layer film.
